(19) United States
(12) Patent Application Publication
(10) Pub. No.: US 2025/0151262 A1
(43) Pub. Date: May 8, 2025

(54) MICROELECTRONIC DEVICES, AND RELATED METHODS, MEMORY DEVICES, AND ELECTRONIC SYSTEMS

(71) Applicant: Micron Technology, Inc., Boise, ID (US)

(72) Inventors: Ping Kao, Taichung City (TW); Soichi Sugiura, Boise, ID (US); Yoshihiro Matsumoto, Sagamihara (JP); Cheng En Lue, Sagamihara (JP)

(21) Appl. No.: 18/905,905

(22) Filed: Oct. 3, 2024

Related U.S. Application Data
(60) Provisional application No. 63/595,944, filed on Nov. 3, 2023.

(51) Int. Cl. H10B 12/00

(52) U.S. Cl. CPC H10B 12/485; H10B 12/315; H10B 12/34

(57) ABSTRACT

A microelectronic device includes a semiconductor base structure, word lines, digit line contacts, digit lines, and storage node contacts. The semiconductor base structure includes pillar structures horizontally separated from one another by filled isolation trenches. The word lines horizontally extend through the pillar structures and the filled isolation trenches in a first direction. The digit line contacts include conductively doped semiconductor material vertically extending into digit line contact sections of the pillar structures. The digit lines are over and in contact with the digit line contacts and horizontally extend in a second direction orthogonal to the first direction. The digit lines have a different material composition than the digit line contacts. The storage node contacts include additional conductively doped semiconductor material vertically extending into storage node contact sections of the pillar structures. Methods, memory devices, and electronic systems are also described.

### CROSS-REFERENCE TO RELATED APPLICATION

This application claims the benefit under 35 U.S.C. § 119(e) of U.S. Provisional Patent Application Ser. No. 63/595,944, filed Nov. 3, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices, and to related methods, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

A relatively common microelectronic device is a memory device. A memory device may include a memory array having a number of memory cells arranged in a grid pattern. One type of memory cell is a dynamic random access memory (DRAM). In the simplest design configuration, a DRAM cell includes one access device, such as a transistor, and one storage device, such as a capacitor. Modern applications for memory devices can utilize vast numbers of DRAM unit cells, arranged in an array of rows and columns. The DRAM cells are electrically accessible through digit lines and word lines arranged along the rows and columns of the array.

A typical access device of a DRAM cell generally includes a channel region between a source region and a drain region, and a gate electrode configured to electrically connect the source region and the drain region to one another through the channel region. The source region and the drain region of the access device usually include heavily conductively doped semiconductive material, and the channel region typically comprises an undoped semiconductive material or an oppositely conductively doped (e.g., relative to the dopant conductivity type of the source/drain regions) semiconductive material. Challenges related to access device fabrication include achieving desirable dopant concentrations and dopant distributions in the source region, the drain region, and the channel region thereof, and reducing fabrication costs. For example, ion implantation processes conventionally employed to impart source regions and drain regions of access devices with desirable heavy dopant concentration levels can be complex, inefficient, and costly to effectuate.

### BRIEF DESCRIPTION OF THE DRAWINGS

FIGS. 1A and 1B are a simplified, partial longitudinal cross-sectional view (FIG. 1A) and simplified, partial top-down view (FIG. 1B) of a microelectronic device structure, in accordance with embodiments of the disclosure.

FIG. 2 is a functional block diagram of a memory device, in accordance with an embodiment of the disclosure.

FIG. 3 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., structures, materials, regions, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni— and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., GaₓIn_{1-X}As_{Y}P_{1-y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnxO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

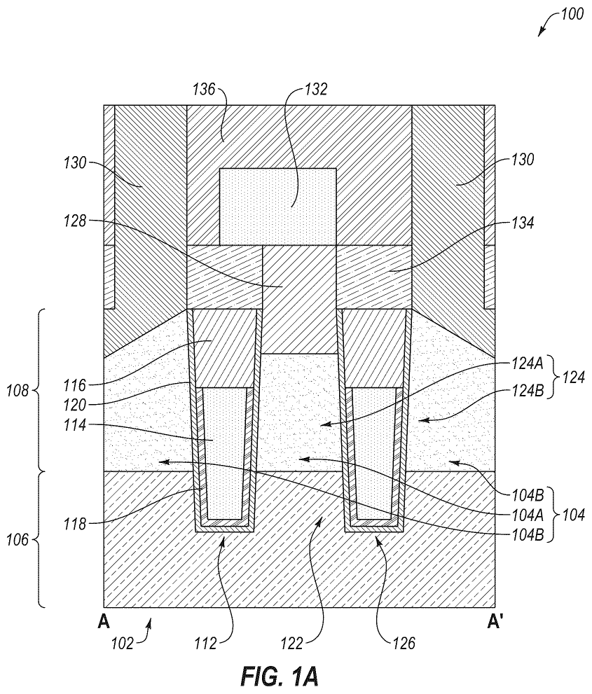

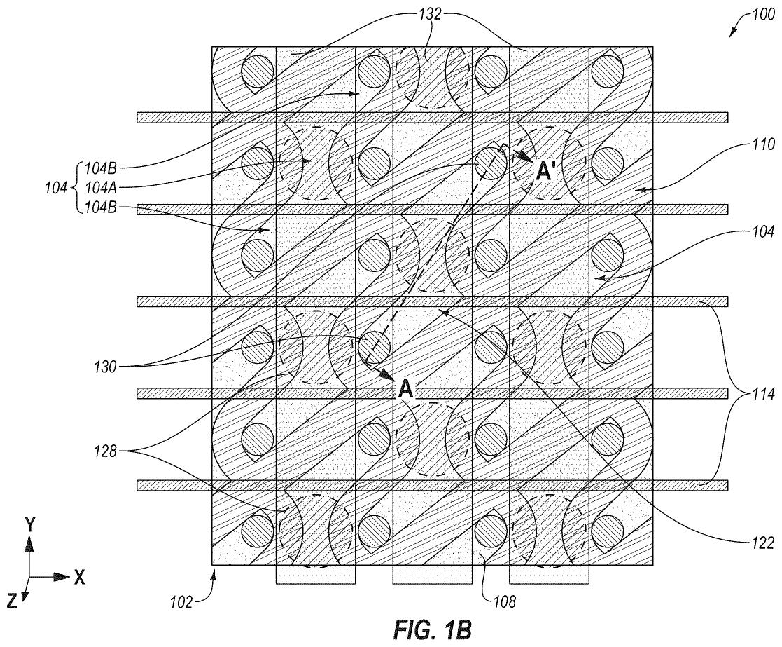

FIG. 1A is a simplified, partial longitudinal cross-sectional views of a microelectronic device structure (e.g., a memory device structure, such as a DRAM structure) for a microelectronic device (e.g., a memory device, such as a DRAM device), in accordance with embodiments of the disclosure. FIG. 1B is a simplified, partial top-down view of the microelectronic device structure 100 shown in FIG. 1A, wherein a line A-A′ corresponds to the longitudinal cross-section of the microelectronic device structure 100 depicted in FIG. 1A. For clarity in understanding the drawings and related description, some features (e.g., structures, materials, regions) of the microelectronic device structure 100 shown in FIGS. 1A and 1B that are depicted in FIG. 1A are not depicted in FIG. 1B, and vice versa. However, it will be understood that any feature depicted in at least one of FIGS. 1A and 1B may be included in the microelectronic device structure 100.

Referring collectively to FIGS. 1A and 1B, the microelectronic device structure 100 may be formed to include a base semiconductor structure 102 and filled trenches 110 (FIG. 1B) vertically extending into the base semiconductor structure 102. The filled trenches 110 horizontally surround and at least partially define pillar structures 104 of the base semiconductor structure 102. The microelectronic device structure 100 may further include additional filled trenches 112 embedded within and horizontally extending through the pillar structures 104 and the filled trenches 110, word line structures 114 (e.g., access line structures, word lines, access lines) within the additional filled trenches 112, and insulative capping structures 116 (e.g., word line capping structures, access line capping structures) within the additional filled trenches 112 and vertically overlying the word line structures 114. In addition, the microelectronic device structure 100 may include digit line contact structures 128 and storage node contact structures 130 vertically overlying and in contact with the pillar structures 104, and digit line structures 132 (e.g., digit lines, data line structures, data lines, bit line structures, bit lines) vertically overlying and in contact with the digit line contact structures 128. The microelectronic device structure 100 may also include additional features (e.g., additional structures, additional devices, additional materials, additional regions), as described in further detail below.

The base semiconductor structure 102 comprises a base material or construction upon which additional features (e.g., materials, structures, devices) of the microelectronic device structure 100 are formed. The base semiconductor structure 102 may comprise a semiconductor structure (e.g., a semiconductor wafer), or a base semiconductor material on a supporting structure. For example, the base semiconductor structure 102 may comprise a conventional silicon substrate (e.g., a conventional silicon wafer), or another bulk substrate comprising a semiconductor material. In some embodiments, the base semiconductor structure 102 comprises a silicon wafer. The base semiconductor structure 102 may include one or more layers, structures, and/or regions formed therein and/or thereon.

The pillar structures 104 may individually vertically extend (e.g., project) from a relatively lower portion of the base semiconductor structure 102 that horizontally extends across and between the pillar structures 104. The pillar structures 104 may be formed of and include semiconductor material (e.g., silicon, such as polycrystalline silicon) of the base semiconductor structure 102, and may be considered so-called “active” regions of the base semiconductor structure 102. The filled trenches 110 may be horizontally interposed between the pillar structures 104 of the base semiconductor structure 102, as described in further detail below. In addition, the pillar structures 104 of the base semiconductor structure 102 may vertically extend beyond upper boundaries of the word line structures 114, and at least to upper boundaries of the insulative capping structures 116, as also described in further detail below.

Still referring collectively to FIGS. 1A and 1B, the pillar structures 104 may individually exhibit an elongate (e.g., non-circular, non-square) horizontal cross-sectional shape (see FIG. 1B) at least partially defined by the horizontal cross-sectional shapes of the filled trenches 110 horizontally adjacent thereto. The pillar structures 104 may individually include an upper surface, opposing horizontal ends, and opposing horizontal sides extending form and between the opposing ends. Intersections of the opposing horizontal ends of an individual pillar structure 104 with the opposing horizontal sides of the pillar structure 104 may define horizontal corners of the pillar structure 104. An individual pillar structure 104 may include a digit line contact section 104A (e.g., bit line contact region) and storage node contact sections 104B (e.g., cell contact regions). As shown in FIG. 1B, the storage node contact sections 104B of the pillar structure 104 may be located proximate the opposing horizontal ends of the pillar structure 104, and the digit line contact section 104A may be horizontally interposed between the storage node contact sections 104B. The digit line contact section 104A may be positioned at or proximate a horizontal center of the pillar structure 104. In some embodiments, as depicted in FIG. 1B, the digit line contact section 104A of an individual pillar structure 104 is horizontally narrower (e.g., in the X-direction) than each of the storage node contact sections 104B of the pillar structure 104. The digit line contact section 104A and the storage node contact sections 104B of an individually pillar structure 104 may be separated from one another by a pair of the additional filled trenches 112, as described in further detail below. Furthermore, as shown in FIG. 1B, for two (2) of the pillar structures 104 horizontally neighboring one another in the X-direction, the digit line contact section 104A of one of the pillar structures 104 may horizontally overlap, in the Y-direction, one of the storage node contact sections 104B of the other of the pillar structures 104.

Referring the FIG. 1A, the pillar structures 104 may respectively further include a well region 106, and an additional region 108 vertically overlying the well region 106. For an individual pillar structure 104, the well region 106 and the additional region 108 of the pillar structure 104 may respectively horizontally extend across (e.g., horizontally span) the digit line contact section 104A and the storage node contact sections 104B of the pillar structure 104.

The well region 106 of an individual pillar structure 104 may be formed of and include conductively doped semiconductor material. The well region 106 may, for example, comprise semiconductor material (e.g., polycrystalline silicon) of the base semiconductor structure 102 doped with at least one conductivity enhancing species, such as at least one P-type dopant (e.g., one or more of boron, aluminum, and gallium) or at least one N-type dopant (e.g., one or more of phosphorus, arsenic, antimony, and bismuth). In some embodiments, the well region 106 is formed of and includes polycrystalline silicon doped with at least one P-type dopant. Thus, the well region 106 may comprise a P-well exhibiting deficiencies of valence electrons (commonly referred to as “holes”). In additional embodiments, the well region 106 is formed of and includes polycrystalline silicon doped with at least one N-type dopant. Thus, the well region 106 may comprise an N-well exhibiting excesses of free electrons.

The additional region 108 of an individual pillar structure 104 may be formed of and include semiconductor material that is not heavily doped with at least one conductivity enhancing species. For example, if the well region 106 vertically underlying the additional region 108 comprises a P-well, the additional region 108 may be not heavily doped with at least one N-type dopant. An N-type dopant concentration of the additional region 108 may, for instance, be less than about 1×10¹⁷ atoms of N-type dopant per cubic centimeter (cm³), such that the additional region 108 is not considered an N+ region. As another example, if the well region 106 vertically underlying the additional region 108 comprises an N-well, the additional region 108 may be not heavily doped with at least one P-type dopant. A P-type dopant concentration of the additional region 108 may, for instance, be less than about 1×10¹⁷ atoms of P-type dopant per cm³, such that the additional region 108 is not considered a P+ region. In some embodiments, the additional region 108 of an individual pillar structure 104 is substantially free of any conductivity enhancing species. The additional region 108 may, for example, comprise semiconductor material (e.g., polycrystalline silicon) substantially free of any P-type dopants and substantially free of any N-type dopants. In further embodiments, at least a portion of the additional region 108 of an individual pillar structure 104 is relatively lightly doped with at least one conductivity enhancing species as a result of migration (e.g., diffusion) of dopant(s) (e.g., N-type dopant(s), P-type dopant(s)) into the additional region 108 from the digit line contact structure 128, the storage node contact structures 130, and/or the well region 106 the during one or more processing (e.g., thermal annealing) acts.

Forming the additional regions 108 of the pillar structures 104 to include semiconductor material that is not heavily doped with at least one conductivity enhancing species eliminates various processing acts (e.g., photolithographic patterning acts, ion implantation acts) otherwise employed by conventional methods to form conventional configurations including pillar structures respectively having a heavily doped region (e.g., N+ region, P+ region) of semiconductor material vertically overlying a well region (e.g., P-well, N-well) of the semiconductor material. The methods of the disclosure may also alleviate abrupt doping profiles associated with convention methods that may otherwise result in undesirable current leakage during use and operation of convention devices formed through such conventional methods.

Referring to FIG. 1B, the pillar structures 104 are separated from one another by the filled trenches 110. The filled trenches 110 may, for example, be employed as shallow trench isolation (STI) structures within the base semiconductor structure 102. A vertical height (e.g., in the Z-direction) of the pillar structures 104 may correspond to (e.g., be the same as) as vertical height (e.g., in the Z-direction) of the filled trenches 110. As shown in FIG. 1B, some of the filled trenches 110 may be positioned adjacent the opposing horizontal ends of the pillar structures 104 and may horizontally extend in substantially linear paths; and others of the filled trenches 110 may be positioned adjacent the opposing horizontal sides of the pillar structures 104, and may horizontally extend in substantially non-linear paths (e.g., wavy paths). The some of the filled trenches 110 may horizontally intersect the others of the filled trenches 110 at or proximate horizontal corners of the pillar structures 104.

The filled trenches 110 may comprise trenches in the base semiconductor structure 102 filled, at least in part, with at least one insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the insulative material of the filled trenches 110 comprises SiOₓ (e.g., SiO₂). The insulative material of the filled trenches 110 may be substantially homogeneous, or the insulative material of the filled trenches 110 may be heterogeneous.

Referring collectively to FIGS. 1A and 1B, the additional filled trenches 112 (FIG. 1A) may vertically overlap and horizontally extend through the pillar structures 104 and the filled trenches 110 (FIG. 1B). In some embodiments, the additional filled trenches 112 horizontally extend in substantially linear paths. For example, referring to FIG. 1B, the additional filled trenches 112 may horizontally extend in parallel with one another in the X-direction, as represented by the paths of the word line structures 114 depicted in FIG. 1B (since the word line structures 114 are positioned within horizontal areas of the additional filled trenches 112 (FIG. 1A)). As used herein, the term “parallel” means substantially parallel.

Within a horizontal area of an individual pillar structure 104, portions of two (2) of the additional filled trenches 112 may be separate (e.g., isolate) the storage node contact sections 104B of the pillar structure 104 from the digit line contact section 104A of the pillar structure 104. The portions of the two (2) of the additional filled trenches 112 may be horizontally interposed between the digit line contact section 104A and the storage node contact sections 104B, and may partially define horizontal boundaries of the digit line contact section 104A and the storage node contact sections 104B. In addition, each of the additional filled trenches 112 may be formed to exhibit substantially the same horizontal dimension(s) and substantially the same horizontal cross-sectional shape(s) as each other of the additional filled trenches 112; or at least one of the additional filled trenches 112 may be formed to exhibit one or more of different horizontal dimension(s) (e.g., relatively larger horizontal dimension(s), relatively smaller horizontal dimension(s)) and different horizontal cross-sectional shape(s) than at least one other of the additional filled trenches 112.

The additional filled trenches 112 (FIG. 1A) may be formed to vertically extend to and terminate at different depths (e.g., vertical elevations) within the base semiconductor structure 102 than the filled trenches 110 (FIG. 1B). For example, the additional filled trenches 112 may vertically extend to and terminate at relatively shallower depths within the base semiconductor structure 102 than the filled trenches 110. In some embodiments, the additional filled trenches 112 each vertically extend through the additional regions 108 of the pillar structures 104 and vertically terminate (e.g., end) within the well regions 106 of the pillar structures 104.

With continued reference to FIGS. 1A and 1B, the word line structures 114 may be formed and positioned within the additional filled trenches 112. As shown in FIG. 1B, the word line structures 114 may exhibit horizontally elongate shapes extending in parallel in the X-direction. An individual word line structure 114 may continuously horizontally extend across (and be shared by) multiple of the pillar structures 104. Within a horizontal area of an individual pillar structure 104, portions of two (2) of the word line structures 114 may be horizontally interposed between the digit line contact section 104A of the pillar structure 104 and the storage node contact sections 104B of the pillar structure 104. As shown in FIG. 1A, uppermost surfaces of the word line structures 114 may vertically underlie uppermost surfaces of the pillar structures 104.

The word line structures 114 may individually be formed of and include conductive material, such as one or more of at least one metal, at least one an alloy, at least one conductive metal-containing material, and at least one conductively doped semiconductor material. By way of non-limiting example, the word line structures 114 may individually formed of and include metallic material, such as one or more of W, Ru, Mo, and TiN_{y}. In some embodiments, the word line structures 114 are individually formed of and include W. The word line structures 114 may each be substantially homogeneous, or more or more of the word line structures 114 may individually be heterogeneous.

As shown in FIG. 1A, the additional filled trenches 112 may respectively further include insulative liner material 118 interposed between the word line structures 114 and the pillar structures 104. The insulative liner material 118 of the additional filled trenches 112 may substantially cover at least side surfaces and bottom surfaces of the word line structures 114. The insulative liner material 118 of the additional filled trenches 112 may intervene between the word line structures 114 and the digit line contact sections 104A and the storage node contact sections 104B of the pillar structures 104. In some embodiments, the insulative liner material 118 of the additional filled trenches 112 is employed as gate dielectric material of access devices 122 (e.g., access transistors) of the microelectronic device structure 100, as described in further detail below.

The insulative liner material 118 may be formed of and include insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the insulative liner material 118 of the additional filled trenches 112 is formed of and includes SiOₓ (e.g., SiO₂). The insulative liner material 118 of the additional filled trenches 112 may be substantially homogeneous, or the insulative liner material 118 of the additional filled trenches 112 may be heterogeneous.

Referring to FIG. 1A, the insulative capping structures 116 may be formed and positioned within the additional filled trenches 112, and may be vertically overlie (in the Z-direction shown in FIG. 1B) and horizontally extend (in the X-direction and the Y-direction shown in FIG. 1B) across the word line structures 114. In some embodiments, the insulative capping structures 116 are employed as word line capping structures (e.g., access line capping structures) of the microelectronic device structure 100. The insulative capping structures 116 may exhibit horizontally elongate shapes extending in parallel in the X-direction (FIG. 1B) and corresponding to the horizontally elongate shapes of the word line structures 114 vertically thereunder. An individual insulative capping structures 116 may continuously horizontally extend across multiple of the pillar structures 104. Within a horizontal area of an individual pillar structure 104, portions of two (2) of the insulative capping structures 116 may be horizontally interposed between the digit line contact section 104A of the pillar structure 104 and the storage node contact sections 104B of the pillar structure 104.

The insulative capping structures 116 may individually be formed of insulative material, such as one or more of a dielectric oxide material (e.g., silicon dioxide; phosphosilicate glass; borosilicate glass; borophosphosilicate glass; fluorosilicate glass; aluminum oxide; a combination thereof), a dielectric nitride material (e.g., SiN_{y}), a dielectric an oxynitride material (e.g., SiOₓN_{y}), a dielectric carbonitride material (e.g., SiCₓN_{y}), and a dielectric carboxynitride material (e.g., SiOₓCyN_{z}), and amorphous carbon. In some embodiments, the insulative capping structures 116 are individually formed of and include silicon nitride (e.g., SiN_{y}, such as Si₃N₄). In additional embodiments, the insulative capping structures 116 are individually formed of and include silicon oxide (e.g., SiOₓ, such as SiO₂). The insulative capping structures 116 may individually be substantially homogeneous, or one or more of the insulative capping structures 116 may be heterogeneous.

Still referring to FIG. 1A, optionally, the additional filled trenches 112 may respectively further include spacer material 120 substantially continuously extending on or over surfaces of the microelectronic device structure 100 defining boundaries of the additional filled trenches 112. The spacer material 120 may be interposed between the pillar structures 104 and the word line structures 114 and the insulative capping structures 116. The spacer material 120 may be interposed between the insulative capping structures 116 and the pillar structures 104, digit line contact structures 128, and storage node contact structures 130 horizontally neighboring the insulative capping structures 116. The spacer material 120 may also be interposed between the insulative liner material 118 and the pillar structures 104. As shown in FIG. 1A, in some embodiments, for an additional filled trench 112, the spacer material 120 thereof substantially covers side surfaces of the insulative capping structure 116 thereof as well as outer side surfaces and a bottom surface of the insulative liner material 118 thereof. In additional embodiments, for an additional filled trench 112, the spacer material 120 thereof substantially covers side surfaces of the insulative capping structures 116, but does not substantially cover the outer side surfaces and the bottom surface of the insulative liner material 118 thereof. In further embodiments, the spacer material 120 is omitted (e.g., absent) from the microelectronic device structure 100.

The spacer material 120, if any, may be formed of and include insulative material. In some embodiments, the spacer material 120 is formed of and includes dielectric oxide material (e.g., SiO_{y}, such as SiO₂). In some embodiments, the spacer material 120 is formed of and includes dielectric nitride material (e.g., SiN_{y}, such as Si₃N₄). In additional embodiments, the spacer material 120 is formed of and includes low-K (low-dielectric constant) dielectric material, such as one or more of silicon oxycarbide (SiOₓC_{y}), silicon oxynitride (SiOₓN_{y}), hydrogenated silicon oxycarbide (SiCₓO_{y}H_{z}), and silicon oxycarbonitride (SiOₓC_{z}N_{y}). In addition, the spacer material 120, if any, may be formed to have a thickness within a range of from about 1 nm to about 5 nm, such as from about 2 nm to about 4 nm, or from about 2 nm to about 3 nm.

The access devices 122 of the microelectronic device structure 100 may respectively include source/drain regions 124 (e.g., a source region 124A and a drain region 124B), a channel region 126, a gate structure (e.g., a gate electrode), and a gate dielectric structure. The source/drain regions 124 of an individual access device 122 may be within the additional region 108 of an individual pillar structure 104. The channel region 126 of the access device 122 may be horizontally interposed between the source/drain regions 124 and may be within the well region 106 of the pillar structure 104. The gate structure of the access device 122 may comprise a portion of one of the word line structures 114. The gate dielectric structure of the access device 122 may comprise a portion of at least the insulative liner material 118 (and a portion of the spacer material 120, if any) intervening between the gate structure and the channel region 126 of the access device 122. As shown in FIG. 1A, in some embodiments, each of the pillar structures 104 includes two (2) of the access devices 122 within a horizontal area thereof.

With continued reference to FIG. 1A, isolation material 134 may be formed and positioned on or over the pillar structures 104, the filled trenches 110, and the additional filled trenches 112 (including the insulative capping structures 116 thereof). The isolation material 134 may substantially cover uppermost surfaces of the pillar structures 104, the filled trenches 110, and the insulative capping structures 116 within the additional filled trenches 112. The isolation material 134 may be formed of and include insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). The isolation material 134 may be substantially homogeneous, or the isolation material 134 may be heterogeneous. In some embodiments, the isolation material 134 is formed of and includes dielectric oxide material (e.g., SiOₓ, such as SiO₂). The isolation material 134 may be formed to have a desirable vertical height (e.g., in the Z-direction shown in FIG. 1B), such as a vertical height within a range of from about 5 nanometers (nm) to about 15 nm, from about 7 nm to about 12 nm, or about 10 nm.

The digit line contact structures 128 of the microelectronic device structure 100 may respectively vertically extend through the isolation material 134 and into the pillar structures 104 of the base semiconductor structure 102. As described in further detail below, the digit line contact structures 128 horizontally overlap (e.g., in the X-direction and the Y-direction shown in FIG. 1B) the digit line contact sections 104A of the pillar structures 104.

With reference to FIG. 1A, the digit line contact structures 128 may be formed to vertically extend completely through the isolation material 134 and partially through the pillar structures 104 of the base semiconductor structure 102. The digit line contact structure 128 may respectively contact (e.g., physically contact, electrically contact) the digit line contact section 104A of an individual pillar structure 104 of the base semiconductor structure 102. For an individual digit line contact structure 128, a lower boundary (e.g., bottom) of the digit line contact structure 128 may be vertically positioned within the additional region 108 of the pillar structure 104 in contact therewith. In some embodiments, the lower boundary of the digit line contact structure 128 is vertically positioned between upper boundaries and lower boundaries of the insulative capping structures 116 most horizontally proximate thereto. In addition, for an individual digit line contact structure 128, an upper boundary (e.g., top) of the digit line contact structure 128 may be vertically positioned above the upper boundaries of the insulative capping structures 116 most horizontally proximate thereto. In some embodiments, the upper boundaries of the digit line contact structures 128 are substantially coplanar with an upper boundary of the isolation material 134.

Referring collectively to FIGS. 1A and 1B, the digit line contact structures 128 may be substantially horizontally centered about the digit line contact sections 104A of the pillar structures 104. In FIG. 1B the digit line contact structures 128 are depicted using dashed lines to indicate that the digit line contact structures 128 vertically underlie (e.g., in the Z-direction) and are covered by the digit line structures 132. As shown in FIG. 1B, an individual digit line contact structure 128 may be horizontally interposed between two (2) of the word line structures 114 (and, hence, two (2) of the additional filled trenches 112 (FIG. 1A)) neighboring one another in the Y-direction; may be horizontally interposed between two (2) of the filled trenches 110 neighboring one another in the X-direction; and may be horizontally interposed between two (2) of the storage node contact sections 104B of an individual pillar structure 104 in an additional horizontal direction angled relative to the Y-direction and the X-direction.

An individual digit line contact structure 128 may be coupled to one of the source/drain regions 124 (e.g., the source region 124A) of an individual access device 122 of the microelectronic device structure 100. As shown in FIG. 1A, within the horizontal area of an individual pillar structure 104, an individual digit line contact structure 128 may be coupled to two (2) (e.g., a pair) of the access devices 122 operatively associated with the pillar structure 104. For example, the two (2) of the access devices 122 may share a source region 124A within the additional region 108 of the pillar structure 104 with one another, and the digit line contact structure 128 may be coupled to the shared source region 124A of the two (2) of the access devices 122.

The digit line contact structures 128 may respectively be formed of and include semiconductor material heavily doped with at least one conductivity enhancing species (e.g., N-type dopant or P-type dopant). A conductivity type of the conductivity enhancing species of the digit line contact structure 128 may be the opposite of the conductivity type of the conductivity enhancing species of the well region 106 of the pillar structure 104 operatively associated with the digit line contact structure 128. For example, if the well region 106 of the pillar structure 104 comprises a P-well, the digit line contact structure 128 may be formed of and include semiconductor material (e.g., polycrystalline silicon) heavily doped with at least one N-type dopant. An N-type dopant concentration of the digit line contact structure 128 may, for instance, be within a range of from about 1×10¹⁷ atoms of N-type dopant per cm³ to about 1×10²¹ atoms of N-type dopant per cm³, such that the digit line contact structure 128 is formed of and includes N+ semiconductor material. In some embodiments, the digit line contact structures 128 are formed of and include N+ polycrystalline silicon. As another example, if the well region 106 of the pillar structure 104 comprises an N-well, the digit line contact structure 128 may be formed of include semiconductor material (e.g., polycrystalline silicon) heavily doped with at least one P-type dopant. A P-type dopant concentration of the digit line contact structure 128 may, for instance, be within a range of from about 1×10¹⁷ atoms of P-type dopant per cm³ to about 1×10²¹ atoms of P-type dopant per cm³, such that the digit line contact structure 128 is formed of and includes P+ semiconductor material. In some embodiments, the digit line contact structures 128 are formed of and include P+ polycrystalline silicon.

The digit line contact structure 128 may respectively be substantially homogeneous or may respectively be heterogeneous. In some embodiments, each of the digit line contact structures 128 is substantially homogeneous. For example, dopant concentration may be substantially uniform (e.g., may not substantially vary) throughout a vertical thickness (e.g., a vertical height) of an individual digit line contact structure 128. In additional embodiments, one or more (e.g., each) of the digit line contact structures 128 is heterogeneous. For example, dopant concentration may vary (e.g., may be non-uniform) throughout a vertical thickness (e.g., a vertical height) of an individual digit line contact structure 128. The varying dopant concentration may form a non-uniform (e.g., variable) dopant concentration profile within the digit line contact structure 128. In some embodiments, dopant concentration gradually changes (as opposed to abruptly changing) throughout a vertical thickness of an individual digit line contact structure 128. For example, the dopant concentration may vary continuously (e.g., change progressively, such as linearly, parabolically) throughout different portions of the digit line contact structure 128. During use and operation of a microelectronic device including the microelectronic device structure 100, a gradually changing dopant concentration profile of the digit line contact structure 128 may impede or prevent sudden electrical field changes that may otherwise effectuate undesirable current leakage and/or reliability degradation.

To form the digit line contact structures 128, portions of the isolation material 134 and the digit line contact sections 104A of the pillar structures 104 may be removed to form digit line contact openings, and then heavily doped semiconductor material may be formed (e.g., deposited) within and may substantially fill the digit line contact openings. Thereafter portions of the heavily doped semiconductor material overlying an upper boundary (e.g., an upper surface) of the isolation material 134 may be removed (e.g., by way of a CMP process) to expose the isolation material 134 and form the digit line contact structure 128.

Referring collectively to FIGS. 1A and 1B, the digit line structures 132 (e.g., bit line structures, data line structures) may be formed over and in contact (e.g., physical contact, electrical contact) with the digit line contact structures 128. As shown in FIG. 1B, the digit line structures 132 may exhibit horizontally elongate shapes, and may horizontally extend in parallel with one another in the Y-direction (and, hence, orthogonal to the word line structures 114 horizontally extending in parallel with one another in the X-direction). An individual digit line structure 132 may horizontally overlap (e.g., in the X-direction) and be coupled to multiple (e.g., a column) of the digit line contact structures 128.

The digit line structures 132 may individually be formed of and include conductive material, such as one or more of at least one elemental metal (e.g., W, Ti, Mo, Nb, V, Hf, Ta, Cr, Zr, Fe, Ru, Os, Co, Rh, Ir, Ni, Pd, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), and a conductive metal-containing material (e.g., a conductive metal nitride, a conductive metal carbide, a conductive metal oxide). The digit line structures 132 may respectively have a material composition that is different than a material composition of the digit line contact structure 128 in contact therewith. By way of non-limiting example, the digit line structures 132 may individually formed of and include metallic material, such as one or more of W, Ru, Mo, and TiN_{y}. In some embodiments, the digit line structures 132 are individually formed of and include W. The digit line structures 132 may each be substantially homogeneous, or more or more of the digit line structures 132 may individually be heterogeneous.

Referring to FIG. 1A, additional isolation material 136 may be formed on or over digit line structures 132 and the isolation material 134. The additional isolation material 136 may cover upper surfaces and side surfaces of the digit line structures 132 and may also cover an upper surface of the isolation material 134. The additional isolation material 136 may be formed of and include insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). The additional isolation material 136 may be substantially homogeneous, or the isolation material 134 may be heterogeneous. A material composition of the additional isolation material 136 may be substantially the same as a material composition of the isolation material 134, or the material composition of the additional isolation material 136 may be different than the material composition of the isolation material 134. In some embodiments, the material composition of the additional isolation material 136 is different than the material composition of the isolation material 134. The material composition of the additional isolation material 136 may, for example, be selected such that the additional isolation material 136 has etch selectivity relative to the isolation material 134.

The storage node contact structures 130 of the microelectronic device structure 100 may respectively vertically extend through the additional isolation material 136 and the isolation material 134 and into the pillar structures 104 of the base semiconductor structure 102. As described in further detail below, the storage node contact structures 130 horizontally overlap (e.g., in the X-direction and the Y-direction shown in FIG. 1B) the storage node contact sections 104B of the pillar structures 104.

With reference to FIG. 1A, the storage node contact structures 130 may be formed to vertically extend through the additional isolation material 136 and the isolation material 134 and partially through the pillar structures 104 of the base semiconductor structure 102. The storage node contact structures 130 may respectively contact (e.g., physically contact, electrically contact) one of the storage node contact sections 104B of an individual pillar structure 104 of the base semiconductor structure 102. For an individual storage node contact structure 130, a lower boundary (e.g., bottom) of the storage node contact structure 130 may be vertically positioned within the additional region 108 of the pillar structure 104 in contact therewith. In some embodiments, the lower boundary of the storage node contact structure 130 is vertically positioned between upper boundaries and lower boundaries of the insulative capping structures 116 most horizontally proximate thereto. In addition, for an individual storage node contact structure 130, an upper boundary (e.g., top) of the storage node contact structure 130 may be vertically positioned above upper boundaries of the digit line structures 132 most horizontally proximate thereto.

Referring collectively to FIGS. 1A and 1B, the storage node contact structures 130 horizontally overlap the storage node contact sections 104B of the pillar structures 104. As shown in FIG. 1B, an individual storage node contact structure 130 may be horizontally interposed between two (2) of the word line structures 114 (and, hence, two (2) of the additional filled trenches 112 (FIG. 1A)) neighboring one another in the Y-direction; may be horizontally interposed between two (2) of the filled trenches 110 neighboring one another in the X-direction; and may horizontally neighbor the digit line contact section 104A of an individual pillar structure 104 in an additional horizontal direction angled relative to the Y-direction and the X-direction.

The storage node contact structures 130 may individually be formed to have a desirable geometric configuration (e.g., dimensions, such as horizontal dimensions and vertical dimension(s); shape, such as horizontal cross-sectional shape(s) and vertical cross-sectional shape(s)). As shown in FIG. 1A, in some embodiments, the storage node contact structures 130 respectively exhibit variable horizontal cross-sectional dimensions and variable horizontal cross-sectional shapes across the vertical height thereof. For example, a portion of an individual storage node contact structure 130 positioned between an upper boundary and a lower boundary of the additional region 108 of the pillar structure 104 in contact with the storage node contact structure 130 may have one or more of different horizontal dimension(s) and different horizontal cross-sectional shape(s) than an additional portion of the storage node contact structure 130 within vertically overlying the upper boundary of the additional region 108 of the pillar structure 104. In additional embodiments, the storage node contact structures 130 respectively exhibit substantially uniform (e.g., substantially non-variable) horizontal cross-sectional dimensions and/or a substantially uniform (e.g., substantially non-variable) horizontal cross-sectional shape across the vertical height thereof. In addition, each of the storage node contact structures 130 may be formed to exhibit substantially the geometric configuration (e.g., substantially the same dimensions, and substantially same shape) as each other of the storage node contact structures 130, or at least one of the storage node contact structures 130 may be formed to exhibit a different geometric configuration (e.g., different dimension(s) and/or a different shape) than at least one other of the storage node contact structures 130.

An individual storage node contact structure 130 may be coupled to one of the source/drain regions 124 (e.g., the drain region 124B) of an individual access device 122 of the microelectronic device structure 100. As shown in FIG. 1A, within the horizontal area of an individual pillar structure 104, an individual storage node contact structure 130 may be coupled to one (1) of the two (2) (e.g., a pair) of the access devices 122 operatively associated with the pillar structure 104. For example, the two (2) of the access devices 122 have separate drain regions 124B than one another within the additional region 108 of the pillar structure 104, and the individual storage node contact structure 130 may be coupled to the drain region 124B of one (1) of the two (2) of the access devices 122. An individual pillar structure 104 may have two (2) storage node contact structures 130 in contact therewith.

The storage node contact structures 130 may respectively be formed of and include semiconductor material heavily doped with at least one conductivity enhancing species (e.g., N-type dopant or P-type dopant). A conductivity type of the conductivity enhancing species of the storage node contact structures 130 may be the same as the conductivity type of the conductivity enhancing species of the digit line contact structures 128, and may be the opposite of the conductivity type of the conductivity enhancing species of the well region 106 of the pillar structure 104 operatively associated with the storage node contact structures 130. For example, if the well region 106 of the pillar structure 104 comprises a P-well, the storage node contact structures 130 may be formed of and include semiconductor material (e.g., polycrystalline silicon) heavily doped with at least one N-type dopant. An N-type dopant concentration of the storage node contact structures 130 may, for instance, be within a range of from about 1×10¹⁷ atoms of N-type dopant per cm³ to about 1×10²¹ atoms of N-type dopant per cm³, such that the storage node contact structures 130 are individually formed of and include N+ semiconductor material. In some embodiments, the storage node contact structures 130 are respectively formed of and include N+ polycrystalline silicon. As another example, if the well region 106 of the pillar structure 104 comprises an N-well, the storage node contact structures 130 may respectively be formed of include semiconductor material (e.g., polycrystalline silicon) heavily doped with at least one P-type dopant. A P-type dopant concentration of the storage node contact structures 130 may, for instance, be within a range of from about 1×10¹⁷ atoms of P-type dopant per cm³ to about 1×10²¹ atoms of P-type dopant per cm³, such that the storage node contact structures 130 are individually formed of and includes P+ semiconductor material. In some embodiments, the storage node contact structures 130 are respectively formed of and include P+ polycrystalline silicon.

The storage node contact structures 130 may respectively be substantially homogeneous or may respectively be heterogeneous. In some embodiments, each of the storage node contact structures 130 is substantially homogeneous. For example, dopant concentration may be substantially uniform (e.g., may not substantially vary) throughout a vertical thickness (e.g., a vertical height) of an individual storage node contact structure 130. In additional embodiments, one or more (e.g., each) of the storage node contact structures 130 is heterogeneous. For example, dopant concentration may vary (e.g., may be non-uniform) throughout a vertical thickness (e.g., a vertical height) of an individual storage node contact structure 130. The varying dopant concentration may form a non-uniform (e.g., variable) dopant concentration profile within the storage node contact structure 130. In some embodiments, dopant concentration gradually changes (as opposed to abruptly changing) throughout a vertical thickness of an individual storage node contact structure 130. For example, the dopant concentration may vary continuously (e.g., change progressively, such as linearly, parabolically) throughout different portions of the storage node contact structure 130. During use and operation of a microelectronic device including the microelectronic device structure 100, a gradually changing dopant concentration profiles of the storage node contact structure 130 may impede or prevent sudden electrical field changes that may otherwise effectuate undesirable current leakage and/or reliability degradation.

In some embodiments, each of the storage node contact structures 130 has a material composition that is substantially the same as a material composition of each other of the storage node contact structures 130 and that is also substantially the same as a material composition of each of the digit line contact structures 128. In additional embodiments, at least one (e.g., each) of the storage node contact structures 130 has a material composition that is different than a material composition of at least one (e.g., each) of the digit line contact structures 128. In further embodiments, at least one of the storage node contact structures 130 has a material composition that is different than a material composition of at least one other of the storage node contact structures 130.

To form the storage node contact structures 130, portions of the additional isolation material 136, the isolation material 134, and the storage node contact sections 104B of the pillar structures 104 may be removed to form storage node contact openings, and then heavily doped semiconductor material may be formed (e.g., deposited) within and may substantially fill the storage node contact openings. Thereafter portions of the heavily doped semiconductor material overlying an upper boundary (e.g., an upper surface) of the additional isolation material 136 may be removed (e.g., by way of a CMP process) to expose the additional isolation material 136 and form the storage node contact structures 130.

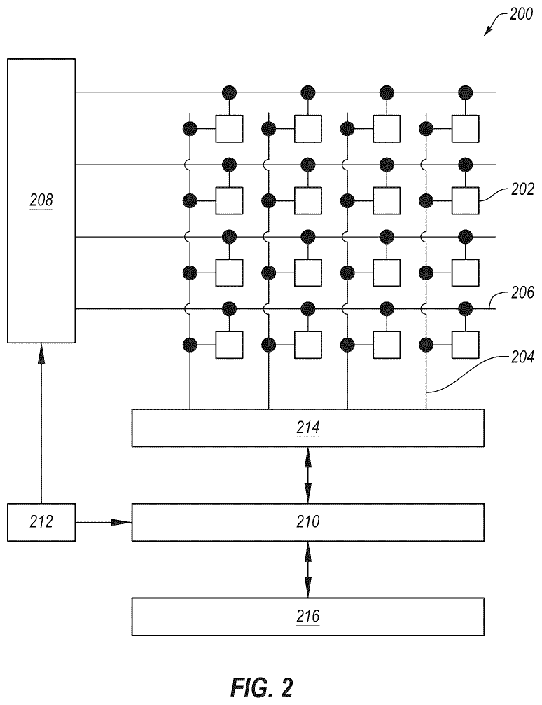

After the formation of the storage node contact structures 130, the microelectronic device structure 100 may be subjected to additional processing. For example, conductive redistribution layer (RDL) structures may be formed vertically over and in electrical communication with the storage node contact structures 130, and storage node devices (e.g., capacitors) may be formed vertically over and in electrical communication with the conductive RDL structures. The conductive RDL structures may be formed to facilitate a horizontal pattern (e.g., a horizontal arrangement) for the conductive RDL structures and the storage node devices that is different (e.g., at least partially horizontally offset from) a horizontal pattern of the storage node contact structures 130. In some embodiments, a hexagonal pattern (e.g., a hexagonal arrangement, a hexagonal grid, a hexagonal array) of the storage node devices (and the conductive RDL structures) is formed. The hexagonal pattern of the storage node devices may exhibit a repeating horizontal arrangement of seven (7) storage node devices, wherein one (1) of the seven (7) storage node devices is substantially horizontally centered between six (6) other of the seven (7) storage node devices. The conductive RDL structures and the storage node devices may be coupled to the storage node contact structures 130. The conductive RDL structures (and the storage node devices) may at least partially horizontally overlap the storage node contact structures 130. However, horizontal centers of at least some of the conductive RDL structures may be offset from horizontal centers of at least some of the storage node contact structures 130 coupled thereto. The access devices 122 and the storage node devices vertically thereover and coupled thereto by way of the storage node contact structures 130 and the conductive RDL structures may form memory cells (e.g., DRAM cells) of a microelectronic device (e.g., a memory device, such as a DRAM device) including the microelectronic device structure 100, as described in further detail below with reference to FIG. 2.

Microelectronic device structures (e.g., the microelectronic device structure 100) of the disclosure may be included in microelectronic devices of the disclosure. As a non-limiting example, FIG. 2 illustrates a functional block diagram of a memory device 200, in accordance with an embodiment of the disclosure. The memory device 200 may include, for example, an embodiment of the microelectronic device structure 100 previously described with reference to FIGS. 1A and 1B. As shown in FIG. 2, the memory device 200 may include memory cells 202, digit lines 204, word lines 206, a row decoder 208, a column decoder 210, a memory controller 212, a sense device 214, and an input/output device 216.

The memory cells 202 of the memory device 200 are programmable to at least two different logic states (e.g., logic 0 and logic 1). Each memory cell 202 may individually include a storage node device (e.g., capacitor) and an access device (e.g., an access transistor). The access devices may be the access devices 122 previously described herein with reference to FIGS. 1A and 1B. The storage node devices may vertically overlie the access devices (e.g., as previously described with reference to FIGS. 1A and 1B), and may be coupled to the access devices by way of storage node contact structures corresponding to the storage node contact structures 130 previously described herein with reference to FIGS. 1A and 1B (as well as conductive RDL structures vertically overlying and coupled to the storage node contact structures). The storage node device of an individual memory cell 202 stores a charge representative of the programmable logic state (e.g., a charged capacitor may represent a first logic state, such as a logic 1; and an uncharged capacitor may represent a second logic state, such as a logic 0) of the memory cell 202. The access device of the memory cell 202 grants access to the storage node device upon application (e.g., by way of one of the word lines 206) of a minimum threshold voltage to a semiconductive channel thereof for operations (e.g., reading, writing, rewriting) on the storage node device.

The digit lines 204 (e.g., corresponding to the digit line structures 132 (FIGS. 1A and 1B)) are connected to the storage node devices of the memory cells 202 by way of the access devices of the memory cells 202. The word lines 206 (e.g., corresponding to the word line structures 114 (FIGS. 1A and 1B)) extend perpendicular to the digit lines 204, and serve as gate electrodes of the access devices of the memory cells 202. Operations may be performed on the memory cells 202 by activating appropriate digit lines 204 and word lines 206. Activating a digit line 204 or a word line 206 may include applying a voltage potential to the digit line 204 or the word line 206. Each column of memory cells 202 may individually be connected to one of the digit lines 204, and each row of the memory cells 202 may individually be connected to one of the word lines 206. Individual memory cells 202 may be addressed and accessed through the intersections (e.g., cross points) of the digit lines 204 and the word lines 206.

The memory controller 212 may control the operations of memory cells 202 through various components, including the row decoder 208, the column decoder 210, and the sense device 214 (e.g., local I/O device). The memory controller 212 may generate row address signals that are directed to the row decoder 208 to activate (e.g., apply a voltage potential to) predetermined word lines 206, and may generate column address signals that are directed to the column decoder 210 to activate (e.g., apply a voltage potential to) predetermined digit lines 204. The sense device 214 may include sense amplifiers configured and operated to receive digit line inputs from the digit lines selected by the column decoder 210 and to generate digital data values during read operations. The memory controller 212 may also generate and control various voltage potentials employed during the operation of the memory device 200. In general, the amplitude, shape, and/or duration of an applied voltage may be adjusted (e.g., varied), and may be different for various operations of the memory device 200.

During use and operation of the memory device 200, after being accessed, a memory cell 202 may be read (e.g., sensed) by the sense device 214. The sense device 214 may compare a signal (e.g., a voltage) of an appropriate digit line 204 to a reference signal to determine the logic state of the memory cell 202. If, for example, the digit line 204 has a higher voltage than the reference voltage, the sense device 214 may determine that the stored logic state of the memory cell 202 is a logic 1, and vice versa. The sense device 214 may include transistors and amplifiers to detect and amplify a difference in the signals (commonly referred to in the art as “latching”). The detected logic state of a memory cell 202 may be output through the column decoder 210 to the input/output device 216. In addition, a memory cell 202 may be set (e.g., written) by similarly activating an appropriate word line 206 and an appropriate digit line 204 of the memory device 200. By controlling the digit line 204 while the word line 206 is activated, the memory cell 202 may be set (e.g., a logic value may be stored in the memory cell 202). The column decoder 210 may accept data from the input/output device 216 to be written to the memory cells 202. Furthermore, a memory cell 202 may also be refreshed (e.g., recharged) by reading the memory cell 202. The read operation will place the contents of the memory cell 202 on the appropriate digit line 204, which is then pulled up to full level (e.g., full charge or discharge) by the sense device 214. When the word line 206 associated with the memory cell 202 is deactivated, all of memory cells 202 in the row associated with the word line 206 are restored to full charge or discharge.

Thus, in accordance with embodiments of the disclosure, a microelectronic device includes a semiconductor base structure, word lines, digit line contacts, digit lines, and storage node contacts. The semiconductor base structure includes pillar structures horizontally separated from one another by filled isolation trenches. The word lines horizontally extend through the pillar structures and the filled isolation trenches in a first direction. The digit line contacts include conductively doped semiconductor material vertically extending into digit line contact sections of the pillar structures. The digit lines are over and in contact with the digit line contacts and horizontally extend in a second direction orthogonal to the first direction. The digit lines have a different material composition than the digit line contacts. The storage node contacts include additional conductively doped semiconductor material vertically extending into storage node contact sections of the pillar structures.

Furthermore, in accordance with embodiments of the disclosure, a memory device includes a pillar structure, two word line structures, a digit line contact structure, a digit line structure, and two storage node contact structures. The pillar structure includes a well region and an additional region. The well region includes doped semiconductor material. The additional region includes additional semiconductor material vertically overlying the well region. The additional region is divided into two storage node contact sections and a digit line contact section horizontally interposed between the two storage node contact sections. The two word line structures horizontally extend through the pillar structure in a first direction and respectively include conductive material vertically overlapping the well region and the additional region of the pillar structure. The digit line contact structure includes additional doped semiconductor material in contact with the additional semiconductor material within the digit line contact section of the pillar structure. The additional doped semiconductor material has a greater concentration of at least one conductivity enhancing dopant than the additional semiconductor material. The digit line structure includes conductive metallic material vertically over and in contact with the digit line contact structure. The digit line structure horizontally extends in a second direction orthogonal to the first direction. The two storage node contact structures include further doped semiconductor material in contact with the additional semiconductor material within the two storage node contact sections of the pillar structure. The further doped semiconductor material has a greater concentration of the at least one conductivity enhancing dopant than the additional semiconductor material.

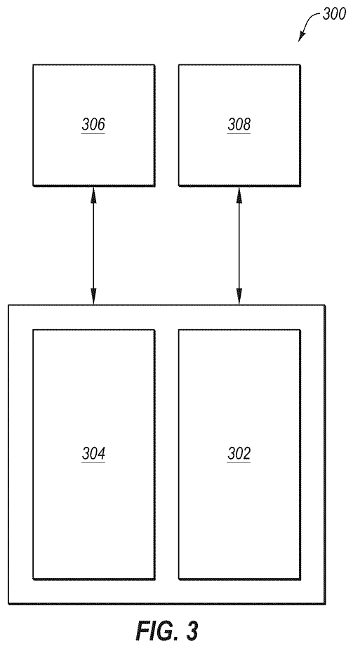

Microelectronic devices (e.g., the memory device 200 previously described herein with reference to FIG. 2) including microelectronic device structures (e.g., the microelectronic device structure 100 previously described herein with reference FIGS. 1A and 1B) in accordance with embodiments of the disclosure may be included in electronic systems of the disclosure. For example, FIG. 3 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 300 includes at least one memory device 302. The memory device 302 may comprise, for example, an embodiment of a microelectronic device (e.g., the memory device 200 shown in FIG. 2) previously described herein. The electronic system 300 may further include at least one electronic signal processor device 304 (often referred to as a “microprocessor”). The electronic signal processor device 304 may, optionally, include an embodiment of a microelectronic device (e.g., the memory device 200 previously described herein with reference to FIG. 2) previously described herein. While the memory device 302 and the electronic signal processor device 304 are depicted as two (2) separate devices in FIG. 3, in additional embodiments, a single (e.g., only one) memory/processor device having the functionalities of the memory device 302 and the electronic signal processor device 304 is included in the electronic system 300. In such embodiments, the memory/processor device may include an embodiment of a microelectronic device structure (e.g., the microelectronic device structure 100 previously described herein with reference to FIGS. 1A and 1B) previously described herein, and/or an embodiment of a microelectronic device (e.g., the memory device 200 previously described herein with reference to FIG. 2) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

Thus, in accordance with embodiments of the disclosure, an electronic system includes an input device, an output device, a processor device operably coupled to the input device and the output device, and a memory device operably coupled to the processor device and including at least one microelectronic device structure. The at least one microelectronic device structure includes pillar structures, word lines, digit line contacts, digit lines, and storage node contacts. The pillar structures are horizontally separated from one another by insulative structures and respectively include a P-well and substantially undoped polysilicon vertically overlying the P-well. The word lines extend through the pillar structures and the insulative structures in a first horizontal direction. The digit line contacts include N+ polysilicon vertically extending into digit line contact sections within the substantially undoped polysilicon of the pillar structures. The digit lines include metallic material on the N+ polysilicon of the digit line contacts and extending in a second horizontal direction orthogonal to the first horizontal direction. The storage node contacts include additional N+ polysilicon vertically extending into storage node contact sections within the substantially undoped polysilicon of the pillar structures.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a semiconductor base structure comprising pillar structures horizontally separated from one another by filled isolation trenches;
word lines horizontally extending through the pillar structures and the filled isolation trenches in a first direction;
digit line contacts comprising conductively doped semiconductor material vertically extending into digit line contact sections of the pillar structures;
digit lines over and in contact with the digit line contacts and horizontally extending in a second direction orthogonal to the first direction, the digit lines having a different material composition than the digit line contacts; and
storage node contacts comprising additional conductively doped semiconductor material vertically extending into storage node contact sections of the pillar structures.

2. The microelectronic device of claim 1, wherein the pillar structures respectively comprise:
a well region comprising further conductively doped semiconductor material; and
an additional region vertically overlying the well region, the pillar structures individually having one of the digit line contact sections and two of the storage node contact sections within the additional region thereof.

3. The microelectronic device of claim 2, wherein the additional region comprises semiconductor material including less than about 1×1017 atoms of any conductivity enhancing dopant per cubic centimeter (cm³).

4. The microelectronic device of claim 2, wherein the additional region comprises substantially undoped semiconductor material.

5. The microelectronic device of claim 2, wherein the further conductively doped semiconductor material of the well region comprises polycrystalline silicon doped with one or more of boron, aluminum, and gallium.

6. The microelectronic device of claim 1, wherein the conductively doped semiconductor material of the digit line contacts and the additional conductively doped semiconductor material of the storage node contacts respectively have a dopant concentration within a range of from about 1×10¹⁷ atoms of dopant per cubic centimeter (cm³) to about 1×10²¹ atoms of dopant per cm³.

7. The microelectronic device of claim 1, wherein the conductively doped semiconductor material of the digit line contacts and the additional conductively doped semiconductor material of the storage node contacts respectively comprise N+ polycrystalline silicon.

8. The microelectronic device of claim 7, wherein the digit line contact sections and the storage node contact sections of the pillar structures do not comprise N+ polycrystalline silicon.

9. The microelectronic device of claim 1, wherein the digit lines respectively comprise one or more of tungsten, ruthenium, molybdenum, and titanium nitride.

10. The microelectronic device of claim 1, further comprising insulative capping structures on upper surfaces of the word lines, lower boundaries of the digit line contacts and the storage node contacts vertically positioned between upper boundaries and lower boundaries of the insulative capping structures.

11. A memory device, comprising:
a pillar structure comprising:
a well region comprising doped semiconductor material; and
an additional region comprising additional semiconductor material vertically overlying the well region, the additional region divided into two storage node contact sections and a digit line contact section horizontally interposed between the two storage node contact sections;
two word line structures horizontally extending through the pillar structure in a first direction and respectively comprising conductive material vertically overlapping the well region and the additional region of the pillar structure;
a digit line contact structure comprising additional doped semiconductor material in contact with the additional semiconductor material within the digit line contact section of the pillar structure, the additional doped semiconductor material having a greater concentration of at least one conductivity enhancing dopant than the additional semiconductor material;
a digit line structure comprising conductive metallic material vertically over and in contact with the digit line contact structure, the digit line structure horizontally extending in a second direction orthogonal to the first direction; and
two storage node contact structures comprising further doped semiconductor material in contact with the additional semiconductor material within the two storage node contact sections of the pillar structure, the further doped semiconductor material having a greater concentration of the at least one conductivity enhancing dopant than the additional semiconductor material.

12. The memory device of claim 11, further comprising an access device within a horizontal area of the pillar structure and comprising:
a source region and a drain region within the additional region of the pillar structure;
a channel region interposed between the source region and the drain region and within the well region of the pillar structure;
a gate structure comprising a portion of one of the two word line structures; and
gate dielectric material interposed between the gate structure and the channel region.

13. The memory device of claim 12, further comprising a storage node device coupled to the access device by way of one of the two storage node contact structures.

14. The memory device of claim 11, wherein the doped semiconductor material of the well region of the pillar structure comprises polycrystalline silicon doped with at least one P-type dopant.

15. The memory device of claim 14, wherein the additional doped semiconductor material of the digit line contact structure and the further doped semiconductor material of the two storage node contact structures respectively comprise additional polycrystalline silicon relatively heavily doped with at least one N-type dopant as compared to the additional semiconductor material of the additional region of the pillar structure.

16. The memory device of claim 15, wherein the additional semiconductor material of the additional region of the pillar structure is substantially free of the at least one N-type dopant.

17. The memory device of claim 11, further comprising:
insulative material interposed between the two word line structures and the pillar structure; and
two insulative line structures vertically overlying the two word line structures and the insulative material and horizontally extending through the pillar structure in the first direction.

18. The memory device of claim 17, further comprising:
isolation material vertically interposed between digit line structure and the two insulative line structures, the digit line contact structure vertically extending through the isolation material and into the additional semiconductor material of the pillar structure; and
additional isolation material vertically overlying the isolation material, the two storage node contact structures vertically extending through the additional isolation material and the isolation material and into the additional semiconductor material of the pillar structure.

19. The memory device of claim 18, wherein the additional isolation material is horizontally interposed between the digit line structure and each of the two storage node contact structures.

20. An electronic system, comprising:
an input device;
an output device;
a processor device operably coupled to the input device and the output device; and
a memory device operably coupled to the processor device and comprising at least one microelectronic device structure comprising:
pillar structures horizontally separated from one another by insulative structures and respectively comprising:
a P-well; and
substantially undoped polysilicon vertically overlying the P-well;
word lines extending through the pillar structures and the insulative structures in a first horizontal direction;
digit line contacts comprising N+ polysilicon vertically extending into digit line contact sections within the substantially undoped polysilicon of the pillar structures;
digit lines comprising metallic material on the N+ polysilicon of the digit line contacts and extending in a second horizontal direction orthogonal to the first horizontal direction; and
storage node contacts comprising additional N+ polysilicon vertically extending into storage node contact sections within the substantially undoped polysilicon of the pillar structures.
